(19) United States
(12) Patent Application Publication
(10) Pub. No.: US 2011/0048754 A1
(43) Pub. Date: Mar. 3, 2011

(54) HOUSING FOR ELECTRONIC DEVICE AND METHOD FOR MAKING THE SAME

(75) Inventors: LIANG XIONG, Shenzhen City (CN); YOU-LI LIU, Shenzhen City (CN); HSIANG-JUNG SU, Shindian (TW); WEN-TE LAI, Shindian (TW)

(73) Assignees: SHENZHEN FUTAIHONG PRECISION INDUSTRY CO., LTD., ShenZhen City (CN); FIH (Hong Kong) Limited, Kowloon (HK)

(21) Appl. No.: 12/720,783

(22) Filed: Mar. 10, 2010

(30) Foreign Application Priority Data
Sep. 3, 2009 (CN) 200910306546.9

(51) Int. Cl. H05K 5/02; C25D 5/02

(52) U.S. Cl. 174/50; 205/122

(57) ABSTRACT

A housing for electronic device, comprising: a substrate, the substrate having an outer surface; a metallic coating formed on at least the outer surface of the substrate, the metallic coating defining a plurality of grooves thereon and forming a pattern; and a metal pattern layer formed in the grooves. A method for making the present housing is also provided.

### BACKGROUND

1. Technical Field

The present disclosure generally relates to housings for electronic devices, especially to a housing having decorative metal patterns, and a method for making the housing.

2. Description of Related Art

Housings for electronic devices, such as mobile phones, decorated with gold may be more attractive. Gold ornaments can be fusion welded on housings. Specifically, a gold welding rod is melted and filled into a groove to form an ornament. However, it is difficult to accurately control the quantity of gold melted into the grooves, resulting in too little or too much gold being used which may degrade the appearance of the housing. Furthermore, fusion welding is only suitable for inlaying simple and large ornaments, so, it is difficult to form complex metal patterns on housing by fusion welding.

Therefore, there is room for improvement within the art.

### BRIEF DESCRIPTION OF THE DRAWINGS

Many aspects of the housing for electronic device and method for making the housing can be better understood with reference to the following drawings. The components in the drawings are not necessarily to scale, the emphasis instead being placed upon clearly illustrating the principles of the present housing and the method for making the same.

FIG. 1 is a schematic front elevational view of an exemplary embodiment of the present housing.

FIG. 2 is a schematic cross-section view of the housing shown in FIG. 1.

FIG. 3 is a schematic drawing of forming a plurality of curve grooves on a substrate of an exemplary process for making the housing shown in FIG. 1.

### DETAILED DESCRIPTION

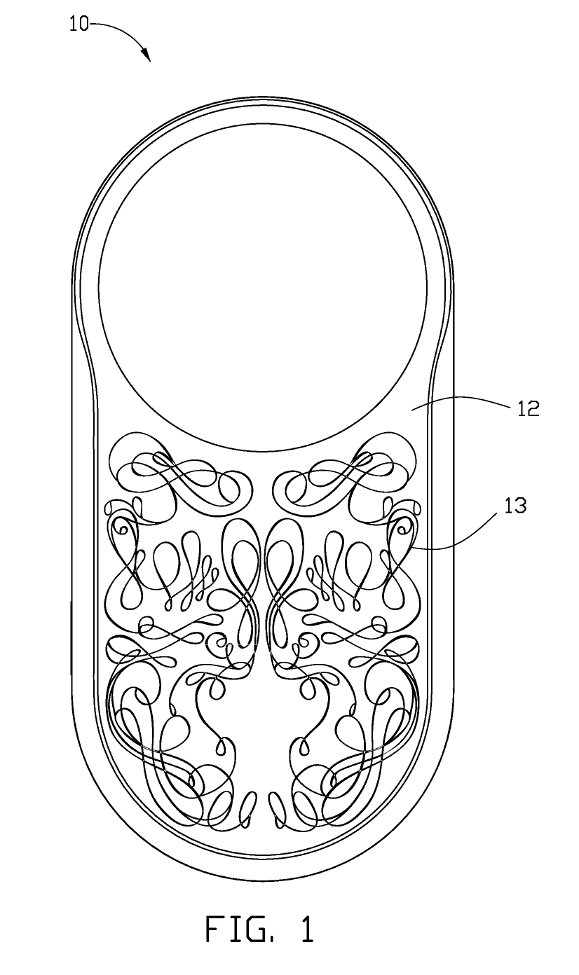

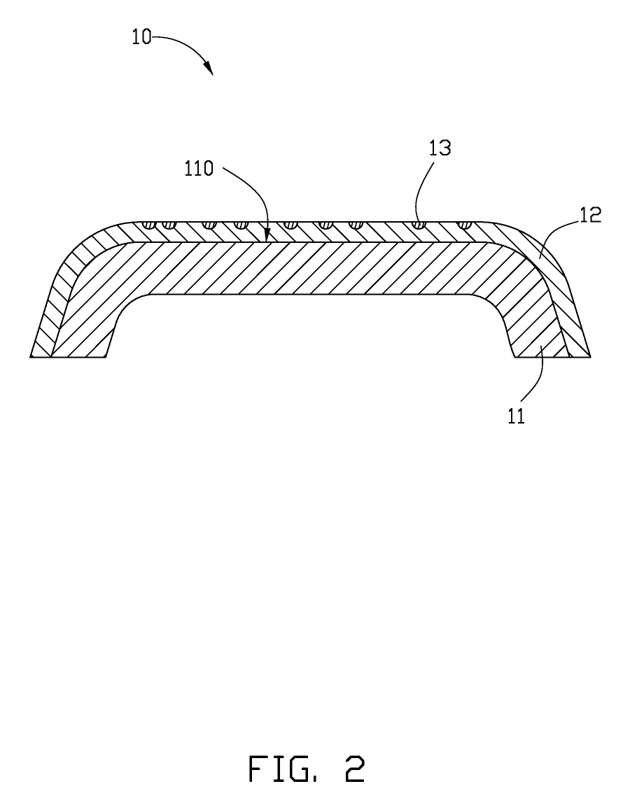

FIGS. 1 and 2 show an exemplary housing 10 for an electronic device such as a mobile phone. The housing 10 includes a substrate 11, a metallic coating 12, and a metal pattern layer 13.

The substrate 11 can be made of metal selected from the group consisting of stainless steel, magnesium alloy, aluminum alloy, and titanium alloy. The substrate 11 is stainless steel in this exemplary embodiment. The substrate 11 has an outer surface 110.

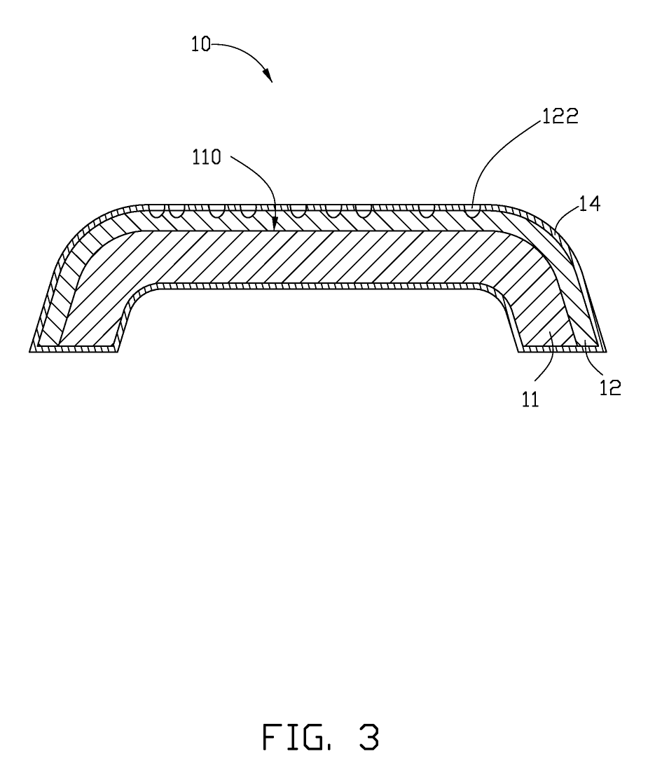

The metallic coating 12 is formed on at least the outer surface 110 of the substrate 11 by electroplating or physical deposition (such as vacuum evaporation or vacuum sputtering). The metallic coating 12 comprises a metal material having a first color, such as chromium, formed by electroplating. The metallic coating 12 defines a plurality of grooves 122 (as shown in FIG. 3) therein. The grooves 122 may be curved and in combination with each other define a desired pattern.

The metal pattern layer 13 fills the grooves 122. The metal pattern layer 13 may be coplanar with or protrude above the metallic coating 12. The metal pattern layer 13 may comprise a noble material such as gold, platinum, or imitation gold. The metal pattern layer 13 has a second color different from the first color of the metallic coating 12.

An exemplary method for making the housing 10 may include the following steps.

A substrate 11 is provided. The substrate 11 has the outer surface 110.

The substrate 11 is pretreated by degreasing and subsequently activating. When the substrate 11 is made of stainless steel, the substrate 11 can be activated in a hydrochloric acid solution containing trivalent iron.

The metallic coating 12 is formed on at least the outer surface 110 by, e.g., electroplating, vacuum evaporation, or vacuum sputtering. For example, the metallic coating 12 may be a chrome coating formed by electroplating. The electroplating process may be carried out in an electrolyte of 28˜25° C. containing a chromic salt, buffers of pH, and necessary additives, at a current density of about 3˜20 A/dm² (ampere per square decimeter).

Referring to FIG. 3, the substrate 12 with the metallic coating 12 is coated with a protective layer 14. The protective layer 14 may be a resin that is resistant to chemical etching and formed by electrophoresis. Alternatively, the protective layer 14 can be a chemical-etching resistant paint sprayed on the metallic coating 12.

Portions of the protective layer 14 and the corresponding metallic coating 12 are removed by, for example, laser carving. The plurality of grooves 122 are defined in the metallic coating 12.

The substrate 11 having the grooves 122 is then electroplated to form a metal pattern layer 13 within the grooves 122. The metal pattern layer 13 may be coplanar with or protrude above the metallic coating 12.

The protective layer 14 is removed. The method for removing the protective layer 14 depends on the respective material of the metallic coating 12 and the metal pattern layer 13. For example, when the metallic coating 12 is made of chrome and the metallic pattern layer 13 is made of gold which are both resistant to strong acids, 98% (by weight) sulfuric acid can be used to remove the protective layer 14.

The substrate 11 can be made of plastic. Accordingly, when the metallic coating 12 is formed by electroplating, the substrate 11 may be processed to be electroconductive before electroplating the metallic coating 12.

When the metallic coating 12 is electroplated with chrome, an electroless plated nickel layer and an electroplated copper layer can be formed between the substrate 11 and the metallic coating 12, for strengthening the bonding of the metallic coating 12 and the substrate 11.

It should be understood, however, that even though numerous characteristics and advantages of the present embodiments have been set forth in the foregoing description, together with details of the structures and functions of the embodiments, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A housing for electronic device, comprising:
a substrate, the substrate having an outer surface;
a metallic coating formed on at least the outer surface of the substrate, the metallic coating defining a plurality of grooves thereon and forming a pattern; and
a metal pattern layer filled in the grooves.

2. The housing as claimed in claim 1, wherein the substrate is made of a metal selected from the group consisting of stainless steel, magnesium alloy, aluminum alloy, and titanium alloy.

3. The housing as claimed in claim 2, wherein the substrate is stainless steel.

4. The housing as claimed in claim 1, wherein the metallic coating and the metal pattern layer have different colors.

5. The housing as claimed in claim 4, wherein the metallic coating is an electroplated chrome coating.

6. The housing as claimed in claim 4, wherein the metal pattern layer is comprised of gold or platinum.

7. The housing as claimed in claim 1, wherein the metal pattern layer is coplanar with or protrude above the metallic coating.

8. A method for making a housing, comprising:
providing a substrate, the substrate having an outer surface;
forming a metallic coating on at least the outer surface of the substrate;
forming a protective layer on the substrate with the metallic coating;
removing portions of the metallic coating and the protective layer to define a plurality of grooves therein that define a pattern;
electroplating a metal pattern layer in the grooves; and
removing the remaining protective layer.

9. The method as claimed in claim 8, wherein the substrate is made of a metal material selected from the group consisting of stainless steel, magnesium alloy, aluminum alloy, and titanium alloy.

10. The method as claimed in claim 9, wherein the substrate is stainless steel.

11. The method as claimed in claim 8, wherein the metallic coating and the metal pattern layer have different colors.

12. The method as claimed in claim 11, wherein the metallic coating comprises chrome.

13. The method as claimed in claim 11, wherein the metal pattern layer comprises gold or platinum.

14. The method as claimed in claim 8, wherein the plurality of grooves are formed by laser carving.

15. The method as claimed in claim 8, wherein the metal pattern layer is coplanar with or protrudes above the metallic coating.

16. The method as claimed in claim 8, wherein the metallic coating is formed by a method selected from electroplating, vacuum evaporation and vacuum sputtering.

17. The method as claimed in claim 8, wherein the protective layer is resin formed by electrophoresis.

18. The method as claimed in claim 8, wherein the protective layer is a paint formed by spraying.
